(19) United States
(12) Patent Application Publication
(10) Pub. No.: US 2026/0110083 A1
(43) Pub. Date: Apr. 23, 2026

(54) SEMICONDUCTOR PROCESSING APPARATUS

(71) Applicant: ASM IP Holding B.V., Almere (NL)

(72) Inventors: Alessandro Viva, Leuven (BE); Ioannis Giannakis, Leuven (BE); Panagiota Arnou, Leuven (BE); Lucian Jdira, Nieuw Vennep (NL); Radko Gerard Bankras, Almere (NL); Riza Yukananto, Utrecht (NL); Davide Proserpio, Zeist (NL); Herbert Terhorst, Amersfoort (NL); Theodorus G.M. Oosterlaken, Oudewater (NL); Simon van Haastert, Veenendaal (NL); Jeroen de Jonge, Almere (NL); Bert Jongbloed, Oud-Heverlee (BE); Chaggai Shmuel Ganani, Almere (NL); Nimit Kothari, Almere (NL)

(21) Appl. No.: 19/359,442

(22) Filed: Oct. 15, 2025

(30) Foreign Application Priority Data
Oct. 18, 2024 (GR) 20240100737

(51) Int. Cl. C23C 16/448; C23C 16/44; C23C 16/455

(52) U.S. Cl. CPC C23C 16/4485; C23C 16/4408; C23C 16/4412; C23C 16/45561

(57) ABSTRACT

A semiconductor processing apparatus is disclosed. The semiconductor processing apparatus comprises a process chamber configured to receive a plurality of substrates; at least one accumulator vessel in fluid communication with the process chamber, configured to store a precursor in gas form; and at least two solid state precursor storage vessels, each being configured to receive a precursor in gas form, to cause said received gas form precursor to be converted to a solid state inside the respective solid state precursor storage vessel, and to cause said solid state precursor to be converted to gas phase. Each of the at least two solid state precursor storage vessels are in fluid communication with the at least one accumulator vessel so as to allow provision of precursor in gas form to the accumulator vessel. The at least one accumulator vessel comprises an actuatable element configured to cause an internal volume of the at least one accumulator vessel to be changed upon actuation.

### CROSS-REFERENCE TO RELATED APPLICATIONS

This application claims priority to Greek Patent Application Serial No. 20240100737, filed Oct. 18, 2024, and titled SEMICONDUCTOR PROCESSING APPARATUS, the disclosure of which is hereby incorporated by reference in its entirety.

### FIELD

The present disclosure relates generally to the field of semiconductor processing methods, and associated structures and apparatus, and to the field of device and integrated circuit manufacture. More particularly the present disclosure generally relates to semiconductor processing apparatus in which precursor may be stored in the solid state.

### BACKGROUND

In the field of semiconductor manufacturing apparatus, batch processing apparatuses, for example vertical furnaces, may provide a significant increase in throughput as compared with single wafer tools which generally process wafers one by one.

However, the amount of precursor required to be provided to a reactor chamber or process chamber of a vertical furnace in order to form a layer of a required thickness on each of a plurality of wafers, or substrates, contained therein, is significantly greater than the amount required to be provided to a reactor chamber of a single wafer tool to form a layer of the same required thickness. Further, in order to provide for example an acceptable throughput and/or a required precursor pressure in the process chamber, the required quantity of precursor may need to be provided within a specific, short time span.

Some precursors, for example ammonia, can be stored in gas form for long periods of time without decomposition. Storage in gas form enables fast and reliable delivery of precursor. Supply of such precursors to the process chamber is relatively straightforward as the required amount of gas can be flowed from a sub-fab supply. Other precursors may decompose when stored in gas form, especially if they are required to be stored at a particular temperature to avoid deposition on surfaces of a container in which a precursor gas is contained, rendering them no longer suitable for use in a deposition process. For such precursors, alternative solutions are needed.

There is a need for apparatus and methods capable of supplying large amounts of gas phase precursor on demand and with high flow rate.

Any discussion, including discussion of problems and solutions, set forth in this section, has been included in this disclosure solely for the purpose of providing a context for the present disclosure, and should not be taken as an admission that any or all of the discussion was known at the time the invention was made or otherwise constitutes prior art.

### BRIEF SUMMARY

This summary introduces a selection of concepts in a simplified form, which are described in further detail below. This summary is not intended to necessarily identify key features or essential features of the claimed subject matter, nor is it intended to be used to limit the scope of the claimed subject matter.

According to a first aspect of the present invention, there is provided a semiconductor processing apparatus comprising a process chamber configured to receive a plurality of substrates, an accumulator vessel in fluid communication with the process chamber, the accumulator vessel being configured to store a precursor in gas form, and at least two solid state precursor storage vessels, each being configured to receive a precursor in gas form, to cause said received gas form precursor to be converted to a solid state inside the respective solid state precursor storage vessel, and to cause said solid state precursor to be converted to gas phase. Each of the at least two solid state precursor storage vessels are in fluid communication with the accumulator vessel so as to allow provision of precursor in gas form to the accumulator vessel. The at least one accumulator vessel comprises an actuatable element configured to cause an internal volume of the at least one accumulator vessel to be changed upon actuation.

Providing the precursor to the solid state precursor storage vessels in gas form may have advantages over provision in liquid or powder form. Provision of the precursor in liquid form, for example being dissolved or otherwise carried by a solvent, to a precursor storage vessel followed by evaporation of the solvent in the vessel requires an additional drying step in the process of (re)filling the precursor storage vessel, may result in solvent contamination of the precursor to be extracted from the vessel, and may be limited in capacity, thus limiting the number of substrates which can be processes, impacting throughput. Providing the precursor in powder form may causing clogging and a carrier gas may be required in order to remove precursor from the vessel.

By providing at least two solid state precursor storage vessels, one of the solid state precursor storage vessels may receive and store precursor while another of the solid state precursor storage vessels may supply precursor to the accumulator vessel, allowing for continuous supply of precursor gas to the accumulator vessel.

By providing the accumulator vessel for short-term storage of precursor gas close to the process chamber, high doses of precursor can be collected and provided to the process chamber in a shorter time period than would be needed for the same amount of precursor gas to be sublimated, allowing for faster provision of precursor to the process chamber and therefore increased throughput.

By providing an accumulator vessel with an actuatable element operable to change the volume of the accumulator vessel, the flow rate of precursor gas to the process chamber can be improved. Additionally, vapor flow rate from a solid state precursor storage vessel to the accumulator vessel can be increased.

At least one accumulator vessel may be provided. For example, two or more accumulator vessels may be provided in parallel. The semiconductor processing apparatus may comprise more than one accumulator vessel, each accumulator vessel being configured to receive precursor gas from at least one of the at least two solid state precursor storage vessels and to provide precursor gas to the process chamber. The more than one accumulator vessels may be connected in parallel such that each accumulator vessel can independently supply precursor gas to the process chamber.

The at least one accumulator vessel may comprise a gas inlet for conducting gas into the respective accumulator vessel and a gas outlet for conducting gas out of the accumulator vessel, wherein the actuatable element is configured to push a gas out of the accumulator vessel via the gas outlet.

The actuatable element may be configured to draw gas into the respective accumulator vessel via the gas inlet. The gas inlet may comprise a gas inlet valve and the gas outlet may comprise a gas outlet valve.

The semiconductor processing apparatus may comprise a controller configured to, in a gas draw mode, control the gas inlet valve to have an open state and the gas outlet valve to have a closed state, and to subsequently cause the actuatable element to be actuated so as to cause a decrease in vapor pressure in one of the at least two solid state precursor storage vessels.

The controller may be configured to, in a gas supply mode, control the gas inlet valve to have a closed state and the gas outlet valve to have an open state, and to subsequently cause the actuatable element to be actuated so as to push a gas out of the accumulator vessel.

The actuatable element may be a piston. The actuatable element may be a bellows.

The accumulator vessel may comprise an accumulator vessel heater.

The accumulator vessel heater may comprise a heating jacket arranged to substantially surround the accumulator vessel.

The accumulator vessel heater may comprise a temperature regulation element between the heating jacket and the accumulator vessel.

The temperature regulation element may comprise a phase change material.

The phase change element may be contained in a thermally conductive container.

The semiconductor processing apparatus may comprise a precursor exhaust path for removing a precursor gas from the process chamber and a reactant exhaust path for removing a reactant gas different to the precursor gas from the process chamber, wherein the precursor exhaust path is separated from the reactant exhaust path.

The precursor exhaust path may comprise a trap for collecting precursor.

The semiconductor processing apparatus may comprise at least two accumulator vessels connected in parallel.

Each of the at least two solid state precursor storage vessels may be in fluid communication with a bulk precursor supply for providing a precursor in gas form.

Providing a fluid communication with a bulk precursor supply allows the at least two solid state precursor storage vessels to be refilled with precursor gas without requiring their removal from the semiconductor processing apparatus, allowing for long uptime of the semiconductor processing apparatus and consequently increased throughput.

Each of the at least two solid state precursor storage vessels may include a respective heater.

Each of the at least two solid state precursor storage vessels may include a respective gas inlet port configured to conduct a precursor in gas form into the respective solid state precursor storage vessel.

The semiconductor processing apparatus may include a first gas line for providing a fluidic connection between a first solid state precursor storage vessel of the at least two solid state precursor storage vessels and the accumulator vessel; and a second gas line for providing a fluidic connection between a second of the at least two solid state precursor storage vessels and the accumulator vessel.

The semiconductor processing apparatus may comprise a first gas flow control valve disposed in the first gas line and a second gas flow control valve in the second gas line. The semiconductor processing apparatus may comprise a controller configured to cause the first gas flow control valve to be set to a closed state while substantially simultaneously causing the second gas flow control valve to be set to an open state.

The semiconductor processing apparatus may include a third gas line for providing a fluidic connection between a bulk precursor supply for providing a precursor in gas form and a first of the at least two solid state precursor storage vessels, and a fourth gas line for providing a fluidic connection between the bulk precursor supply and a second of the at least two solid state precursor storage vessels.

The semiconductor processing apparatus may comprise a third gas flow control valve disposed in the third gas line and a fourth gas flow control valve in the fourth gas line. The semiconductor processing apparatus may comprise a controller configured to cause the third gas flow control valve to be set to an open state while substantially simultaneously causing the fourth gas flow control valve to be set to a closed state.

The semiconductor processing apparatus may comprise a third gas flow control valve heater for heating the third gas flow control valve and a fourth gas flow control valve heater for heating the fourth gas flow control valve.

The accumulator vessel may include an accumulator vessel heater.

The semiconductor processing apparatus may include a fifth gas flow control valve disposed upstream of the accumulator vessel and configured to control a gas flow into the accumulator vessel from any of the at least two solid state precursor storage vessels.

The semiconductor processing apparatus may include a sixth gas flow control valve disposed downstream of the accumulator vessel and configured to control a gas flow from the accumulator vessel into the process chamber.

The semiconductor processing apparatus may comprise a fifth gas flow control valve heater. The semiconductor processing apparatus may comprise a sixth gas flow control valve heater.

Each of the at least two solid state precursor storage vessels may comprise a first heater for heating a section of the respective solid state precursor storage vessel close to the respective gas inlet port and a second heater for heating a section of the respective solid state precursor storage vessel further from the respective gas inlet port.

By allowing independent control of the temperature of different sections of a solid state precursor storage vessel, deposition of precursor at or near the gas inlet port and/or the gas outlet port can be reduced or avoided during sublimation of solid state precursor contained in the solid state precursor storage vessel.

According to a second aspect of the present invention there is provided a method of providing a precursor gas to a process chamber of a semiconductor processing apparatus, the semiconductor processing apparatus including a process chamber configured to receive a plurality of substrates; at least one accumulator vessel in fluid communication with the process chamber, configured to store a precursor in gas form, the at least one accumulator vessel comprising an actuatable element configured to cause an internal volume of the at least one accumulator vessel to be changed upon actuation; at least two solid state precursor storage vessels, each being configured to receive a precursor in gas form, to cause said received gas form precursor to be converted to a solid state inside the respective solid state precursor storage vessel, and to cause said solid state precursor to be converted to gas phase, each of the at least two solid state precursor storage vessels being in fluid communication with the at least one accumulator vessel so as to allow provision of gas phase precursor to the at least one accumulator vessel. The method includes the steps of i) causing a first solid state precursor storage vessel of the at least two solid state precursor storage vessels to receive a precursor in gas form and to convert said precursor to a solid state, ii) causing a second solid state precursor storage vessel of the at least two solid state precursor storage vessels to convert solid state precursor to gas form and to provide precursor in gas form to the accumulator vessel, and iii) causing a precursor gas to be provided to the process chamber from the accumulator vessel by actuating the actuatable element.

Steps i) and ii) may be performed substantially simultaneously. Steps ii) and step iii) may not overlap substantially in time. The method may comprise, after step iii), causing the second solid state precursor storage vessel to receive a precursor in gas form and to convert said precursor to a solid state, and causing the first solid state precursor storage vessel to convert solid state precursor to gas form and to provide precursor in gas form to the accumulator vessel.

Causing a solid state precursor storage vessel to receive a precursor in gas form may comprise causing a bulk precursor supply to provide the precursor in gas form to the solid state precursor storage vessel. Causing a solid state precursor storage vessel to convert a precursor in gas form to solid state may include causing a part of the solid state precursor storage vessel to be cooled to a temperature below a deposition temperature of the precursor. Causing a solid state precursor storage vessel to convert solid state precursor to gas form may include causing a part of the solid state precursor storage vessel to be heated to a temperature above a sublimation temperature of the precursor.

Step iii) may comprise, before actuating the actuatable element, heating the precursor gas. Heating the precursor gas may comprise applying energy to the precursor gas using a heater, a laser, or a microwave radiation device.

According to a third aspect of the present invention there is provided a method of forming a layer on a plurality of substrates using the semiconductor processing apparatus. The method may include the steps of causing the first solid state precursor storage vessel to receive gas precursor from the bulk precursor supply while supplying precursor from the second solid state precursor storage vessel to the accumulator vessel, providing precursor from the accumulator vessel to the process chamber by actuating the actuatable element while causing the first solid state precursor storage vessel to receive gas precursor from the bulk precursor supply, providing a purge gas to the process chamber while causing the first solid state precursor storage vessel to receive gas precursor from the bulk precursor supply and causing the second solid state precursor storage vessel to provide gas precursor to the accumulator vessel, providing a second process gas to the process chamber while causing the first solid state precursor storage vessel to receive gas precursor from the bulk precursor supply and causing the second solid state precursor storage vessel to provide gas precursor to the accumulator vessel, and providing a purge gas to the process chamber while causing the first solid state precursor storage vessel to receive gas precursor from the bulk precursor supply and causing the second solid state precursor storage vessel to provide gas precursor to the accumulator vessel.

In the semiconductor processing apparatus according to the first aspect or the method according to the second or the third aspect, the precursor may comprise molybdenum.

Other technical features may be readily apparent to one skilled in the art from the following figures, descriptions, and claims.

For purposes of summarizing the invention and the advantages achieved over the prior art, certain objects and advantages of the invention have been described herein above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught or suggested herein without necessarily achieving other objects or advantages as may be taught or suggested herein.

All of these embodiments are intended to be within the scope of the invention herein disclosed. These and other embodiments will become readily apparent to those skilled in the art from the following detailed description of certain embodiments having reference to the attached figures, the invention not being limited to any particular embodiment(s) disclosed.

### BRIEF DESCRIPTION OF THE DRAWINGS

Certain embodiments of the present invention will now be described, by way of example, with reference to the accompanying drawings, in which:

FIG. 1 is a schematic view of a semiconductor processing apparatus according to embodiments of the present invention.

FIG. 2 is a schematic cross-sectional view of an accumulator vessel which may be comprised in a semiconductor processing apparatus according to embodiments of the present invention, in a (re)fill state.

FIG. 3 is a schematic cross-sectional view of an accumulator vessel which may be comprised in a semiconductor processing apparatus according to embodiments of the present invention, in a supply state.

FIG. 4 is a schematic cross-sectional view of a bellows accumulator which may be comprised in a semiconductor processing apparatus according to embodiments of the present invention.

FIG. 5 is a schematic cross-sectional view of an accumulator vessel with an accumulator vessel heater which may be comprised in a semiconductor processing apparatus according to embodiments of the present invention.

FIG. 6 is a schematic cross-sectional view of a solid state precursor storage vessel which may be comprised in a semiconductor processing apparatus according to embodiments of the present invention.

FIG. 7 is a schematic cross-sectional view of a process chamber which may be comprised in a semiconductor processing apparatus according to embodiments of the present invention.

FIG. 8 is a schematic view of a process chamber which may be comprised in a semiconductor processing apparatus according to embodiments of the present invention along with gas lines connected to the process chamber.

FIG. 9 is a flow chart of a method according to embodiments of the present invention.

FIG. 10 illustrates gas flow control valve states of the semiconductor processing apparatus during steps S101 and S102 of the method set out in FIG. 10.

FIG. 11 illustrates gas flow control valve states of the semiconductor processing apparatus during step S103 of the method set out in FIG. 10.

FIG. 12 is a flow chart of a deposition method according to embodiments of the present invention.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION

The description of exemplary embodiments of methods and compositions provided below is merely exemplary and is intended for purposes of illustration only. The following description is not intended to limit the scope of the disclosure or the claims. Moreover, recitation of multiple embodiments having indicated features or steps is not intended to exclude other embodiments having additional features or steps or other embodiments incorporating different combinations of the stated features or steps.

Where in the present disclosure two or more elements are referred to as being “in fluid communication”, it is meant that a fluid such as a gas or liquid or mixture thereof can flow between the elements, in one or both directions. The fluid communication may be achieved, for example, by means of a gas line, tube, pipe, inlet, outlet, or any combination thereof. The fluid communication may be interruptible; for example, a valve or other flow control element may be present.

In this disclosure, any two numbers of a variable can constitute a workable range of the variable, and any ranges indicated may include or exclude the endpoints. Additionally, any values of variables indicated (regardless of whether they are indicated with “about” or not) may refer to precise values or approximate values and include equivalents, and may refer to average, median, representative, majority, etc. in some embodiments. Further, in this disclosure, the terms “including,” “constituted by” and “having” can refer independently to “typically or broadly comprising,” “comprising,” “consisting essentially of,” or “consisting of” in some embodiments. In this disclosure, any defined meanings do not necessarily exclude ordinary and customary meanings in some embodiments. In some cases, percentages indicate herein can be relative or absolute percentages.

A number of example materials are given throughout the embodiments of the current disclosure, it should be noted that the chemical formulas given for each of the example materials should not be construed as limiting and that the non-limiting example materials given should not be limited by a given example stoichiometry.

In the specification, it will be understood that the term “on” or “over” may be used to describe a relative location relationship. Another element, film or layer may be directly on a mentioned layer, or another layer (an intermediate layer) or element may be intervened therebetween, or a layer may be disposed on a mentioned layer but not completely cover a surface of the mentioned layer. Therefore, unless the term “directly” is separately used, the term “on” or “over” will be construed to be a relative concept. Similarly to this, it will be understood the term “under”, “underlying”, or “below” will be construed to be relative concepts.

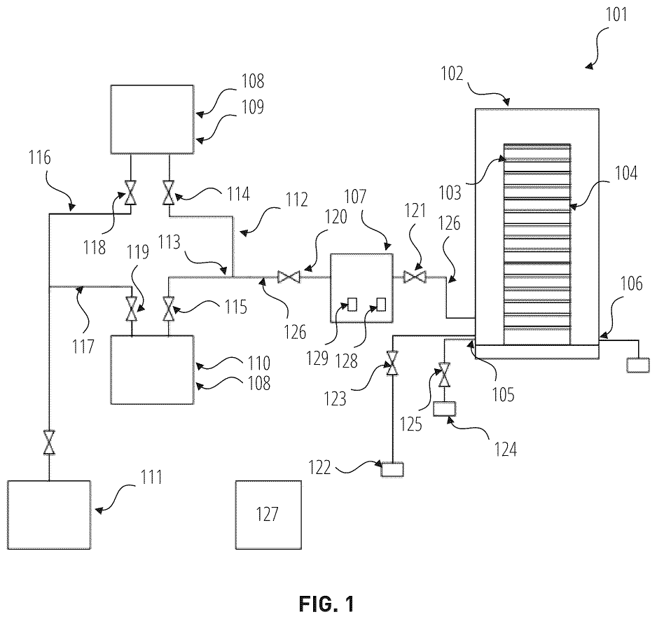

Referring to FIG. 1, a semiconductor processing apparatus 101 according to embodiments of the present invention is shown. The semiconductor processing apparatus 101 comprises a process chamber 102 which is configured to receive a plurality of substrates 103 for processing. The plurality of substrates 103 may be supported by a substrate boat 104. The process chamber 102 comprises at least one process chamber gas flow inlet 105 for allowing a gas to enter the process chamber 102 and at least one process chamber gas exhaust outlet 106 for removing gas from the process chamber 102. The semiconductor processing apparatus 101 comprises an accumulator vessel 107 in fluid communication with the process chamber 102, the accumulator vessel 107 being configured to store precursor in gas form. The semiconductor processing apparatus 101 comprises at least two solid state precursor storage vessels 108, each being in fluid communication with the accumulator vessel 107 so as to allow provision of precursor in gas form to the accumulator vessel 107. Each of the at least two solid state precursor storage vessels 108 are configured to cause said solid state precursor to be converted to gas phase. Although in FIG. 1 two solid state precursor storage vessels 108 are illustrated, it will be understood by the skilled person that more than two solid state precursor storage vessels may be present, for example three or four or more. In the following, a first solid state precursor storage vessel 109 and a second solid state precursor storage vessel 110 are described, without restricting the present invention to embodiments having exactly two solid state precursor storage vessels 108.

The precursor may be a precursor which may be stored in the solid state for long time periods without significant decomposition. When the precursor is required to be transported between components of the semiconductor processing apparatus 101, the precursor may be converted to the gas state; for example, when supplying precursor from the solid state precursor storage vessels 108 to the accumulator vessel 107. The precursor may be stored for relatively short periods of time in gas form, for example in the accumulator vessel 107 before being delivered to the process chamber 102, or in the solid state precursor storage vessels 108 before delivery to the accumulator vessel 107.

Each of the at least two solid state precursor storage vessels 108 may be in fluid communication with a bulk precursor supply 111 for providing a precursor in gas form. The bulk precursor supply 111 may supply precursor in gas state on demand to the solid state precursor storage vessels 108. The bulk precursor supply 111 may store precursor in solid state. The bulk precursor supply 111 may be a sub-fab supply for supplying precursor to multiple semiconductor processing apparatuses 101.

The semiconductor processing apparatus 101 may comprise a first gas line 112 for providing a fluidic connection between a first solid state precursor storage vessel 109 of the at least two solid state precursor storage vessels 108 and the accumulator vessel 107, and a second gas line 113 for providing a fluidic connection between a second solid state precursor storage vessel 110 of the at least two solid state precursor storage vessels 108 and the accumulator vessel 107. The first gas line 112 may include a first gas flow control valve 114 for controlling a flow of precursor gas in the first gas line 112. The second gas line 113 may include a second gas flow control valve 115 for controlling a flow of precursor gas in the second gas line 113. The gas flow control valves 114, 115 may be, for example, valves having only an open position and a closed position, or valves which may be configured to allow a specific amount of gas flow by being neither fully open nor fully closed. The first gas line 112 may include a first gas flow measurement device for measuring a rate of gas flow in the first gas line 112. The second gas line 113 may include a second gas flow measurement device for measuring a rate of gas flow in the second gas line 113.

By providing separate gas lines through which the gas flow is controllable using respective gas flow control valves, the supply of precursor to the accumulator vessel 107 from each of the at least two solid state precursor storage vessels 108 can be controlled.

The semiconductor processing apparatus 101 may comprise a third gas line 116 for providing a fluidic connection between the bulk precursor supply 111 and the first solid state precursor storage vessel 109. The third gas line 116 may include a third gas flow control valve 118 for controlling a flow of precursor gas in the third gas line 116. The semiconductor processing apparatus 101 may comprise a fourth gas line 117 for providing a fluidic connection between the bulk precursor supply 111 and the second solid state precursor storage vessel 110. The fourth gas line 117 may include a fourth gas flow control valve 119 for controlling a flow of precursor gas in the fourth gas line 117.

By providing separate gas lines through which the gas flow is controllable using respective gas flow control valves, the supply of precursor from the bulk precursor supply 111 to the solid state precursor storage vessels 108 can be individually controlled. As will be discussed in more detail hereinafter, this allows for one (or more) of the at least two solid state precursor vessels to supply gas precursor to the accumulator vessel 107 while at the same time one (or more) of the at least two solid state precursor storage vessels 108 is receiving gas precursor from the bulk precursor supply 111.

The semiconductor processing apparatus 101 may comprise a fifth gas flow control valve 120 disposed upstream of the accumulator vessel 107 and configured to control a gas flow into the accumulator vessel 107 from any of the at least two solid state precursor storage vessels 108. The fifth gas flow control valve 120 may in some embodiments not be provided and the third gas flow control valve 118 and fourth gas flow control valve 119 may be used for controlling gas from into the accumulator vessel 107 from the solid state precursor storage vessels 108. The semiconductor processing apparatus 101 may comprise a sixth gas flow control valve 121 disposed between the accumulator vessel 107 and the process chamber 102 for controlling a gas flow from the accumulator vessel 107 into the process chamber 102. The semiconductor processing apparatus 101 may comprise heating means for heating the fifth gas flow control valve 120. The semiconductor processing apparatus 101 may comprise heating means for heating the sixth gas flow control valve 121.

Gas flow control valves used in the semiconductor processing apparatus 101 according to embodiments of the present invention preferably have a high flow conductance, to minimise flow restrictions caused by passage through said valves, and a high operating temperature to ensure any condensation of gas at the valves is minimal.

The semiconductor processing apparatus 101 may comprise a second process gas source 122 in fluid communication with the process chamber 102, for providing a second process gas to the process chamber 102. The second process gas is different to the precursor. A second process gas flow control valve 123 may be provided between the second process gas source 122 and the process chamber 102 for controlling flow of the second process gas to the process chamber 102. The semiconductor processing apparatus 101 may comprise a purge gas source 124 in fluid communication with the process chamber 102, for providing a purge gas to the process chamber 102. A purge gas flow control valve 125 may be provided between the purge gas source 124 and the process chamber 102 for controlling flow of the purge gas to the process chamber 102.

The semiconductor processing apparatus 101 may comprise a fifth gas line 126 providing a fluid connection between the solid state precursor storage vessels 108 and the process chamber 102 and the accumulator vessel 107 may be disposed in the fifth gas line 126. The fifth gas line 126 may comprise the fifth gas flow control valve 120 and the sixth gas flow control valve 121. In some embodiments, the accumulator vessel 107 may be a container having an input in fluid communication with the fifth gas line 126 and an output in fluid communication with the sixth gas line. In some embodiments, the accumulator vessel 107 may be a part of the fifth gas line 126 between the fifth gas flow control valve 120 and the sixth gas flow control valve 121, that is, a separate container may not be provided.

The semiconductor processing apparatus 101 may comprise respective heaters for the gas flow control valves which control gas lines through which precursor gas flows. The heaters may be individually controllable. By heating a gas flow control valve through which precursor gas flows to a temperature above a deposition temperature of the precursor gas, deposition of precursor on the gas flow control valve can be prevented, which can avoid clogging of the gas flow control valves. A gas flow control valve may be heated continuously using its respective heater, or may be heated only when in an open state for allowing precursor gas to flow therethrough.

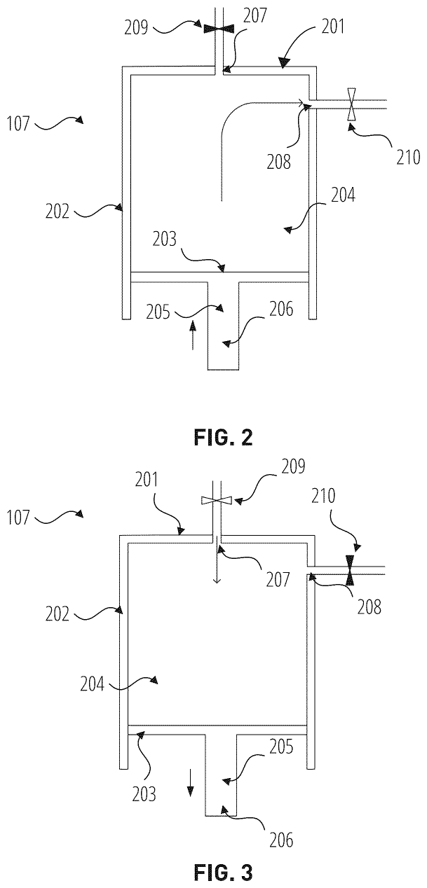

Referring to FIG. 2, an accumulator vessel 107 is shown which may be comprised in the semiconductor processing apparatus 101 according to embodiments of the present invention. The accumulator vessel 107 comprises a top accumulator wall 201, a side accumulator wall 202, and a bottom accumulator wall 203. The accumulator walls enclose an internal volume 204. The accumulator vessel 107 comprises an actuatable element 205, which in FIG. 2 is shown as a piston 206, but which may in some embodiments be a bellows or other type of actuatable element. In FIG. 2, the piston 206 forms the bottom accumulator wall 203, while providing an airtight seal such that air is not allowed into the accumulator vessel 107. The actuatable element 205 is configured to cause the internal volume 204 of the accumulator vessel 107 to be changed upon actuation. For example, the piston 206 may be moved towards the top accumulator wall 201 so as to decrease the internal volume 204 of the accumulator vessel 107. The piston 206 may be moved away from the top accumulator wall 201 so as to increase the internal volume 204 of the accumulator vessel 107.

The accumulator vessel 107 may comprise an accumulator gas inlet 207 for conducting gas into the accumulator vessel 107 and an accumulator gas outlet 208 for conducting gas out of the accumulator vessel 107. The accumulator gas inlet 207 may be provided in the top accumulator wall 201, the side accumulator wall 202, or the bottom accumulator wall 203. In embodiments wherein the actuatable element 205 is a piston 206 which forms a wall of the accumulator vessel 107, the accumulator gas inlet 207 and the accumulator gas outlet 208 may be provided in accumulator walls which are different from the accumulator wall formed by the piston. For example, in some embodiments, the piston 206 may form the bottom accumulator wall 203 and the accumulator gas inlet 207 may be provided in the top accumulator wall 201. In some embodiments, the piston 206 may form the bottom accumulator wall 203 and the accumulator gas inlet 207 may be provided in the side accumulator wall 202. In some embodiments, the piston 206 may form the bottom accumulator wall 203 and the accumulator gas outlet 208 may be provided in the top accumulator wall 201. In some embodiments, the piston 206 may form the bottom accumulator wall 203 and the accumulator gas outlet 208 may be provided in the side accumulator wall 202. In general, the accumulator gas inlet 207 may be positioned such that by actuating the actuatable element 205, gas may be drawn into the accumulator vessel 107 through the accumulator gas inlet 207 and the accumulator gas outlet 208 may be positioned such that by actuating the actuatable element 205, gas may be pushed out of the accumulator vessel 107 through the accumulator gas outlet 208.

The accumulator gas inlet 207 may comprise an accumulator inlet valve 209 for controlling a flow of gas into the accumulator vessel 107. The accumulator gas outlet 208 may comprise an accumulator outlet valve 210 for controlling a flow of gas out of the accumulator vessel 107. In an accumulator vessel (re)fill process in which precursor gas is provided to the accumulator vessel 107 from at least one of the at least two solid state precursor storage vessels 108 through the accumulator gas inlet 207, the accumulator inlet valve 209 may be set to an open state (for example, by controller 127) and the accumulator outlet valve 210 may be set to a closed state (for example, by controller 127), as seen in FIG. 2. In some embodiments, at the beginning of an accumulator vessel (re)fill process, the actuatable element 205 may be in a position or configuration such that the internal volume 204 of the accumulator vessel 107 is smaller than the internal volume 204 of the accumulator vessel 107 at the end of the accumulator vessel (re)fill process. Thus a process of (re)filling the accumulator vessel 107 with precursor gas may comprise causing the actuatable element 205 to be actuated so as to cause the internal volume 204 of the accumulator vessel 107 to increase (for example, by controller 127). With the accumulator outlet valve 210 closed and the accumulator inlet valve 209 open, this may cause a vapor pressure in at least one of the at least two solid state precursor storage vessels 108 to be decreased, which can help to promote sublimation of the solid state precursor, increasing flow rate of the precursor gas into the accumulator vessel 107 and decreasing time to (re)fill the accumulator vessel 107.

The amount of decrease of the internal volume 204 effectuated by the actuatable element 205 during supply of precursor to the process chamber 102 may vary depending on the flow rate of precursor required. The controller 127 may be configured to cause the actuatable element 205 to continue decreasing the volume so as to maintain the flow rate of precursor to the process chamber 102 at a desired value. In embodiments wherein the actuatable element 205 is a piston 206 which forms a wall of the accumulator vessel 107 and the accumulator gas inlet 207 is provided in a wall which is perpendicular to the wall provided by the piston 206, the controller 127 may be configured to prevent the piston 206 from moving past the location of the accumulator gas inlet 207.

In some embodiments, in an accumulator vessel supply process in which precursor gas is provided from the accumulator vessel 107 to the process chamber 102 through the accumulator gas outlet 208, the accumulator inlet valve 209 may be set to a closed state (for example, by controller 127) and the accumulator outlet valve 210 may be set to an open state (for example, by controller 127), as seen in FIG. 3. In some embodiments, at the beginning of an accumulator vessel supply process, the actuatable element 205 may be in a position or configuration such that the internal volume 204 of the accumulator vessel 107 is greater than the internal volume 204 of the accumulator vessel 107 at the end of the accumulator vessel supply process. Thus the accumulator vessel supply process may comprise causing the actuatable element 205 to be actuated so as to cause the internal volume 204 of the accumulator vessel 107 to decrease (for example, by controller 127). This can allow for a greater quantity of precursor gas to be provided to the process chamber 102 within a set time duration as the precursor gas is actively forced from the accumulator vessel 107, as compared with a passive flow situation in which the accumulator outlet valve 210 is opened without a change in the internal volume 204 of the accumulator vessel 107. In addition, by decreasing the internal volume 204 as the quantity of precursor gas in the accumulator vessel 107 decreases, a drop in the temperature of the accumulator vessel 107 caused by a drop in internal pressure of the accumulator vessel 107 can be avoided or reduced.

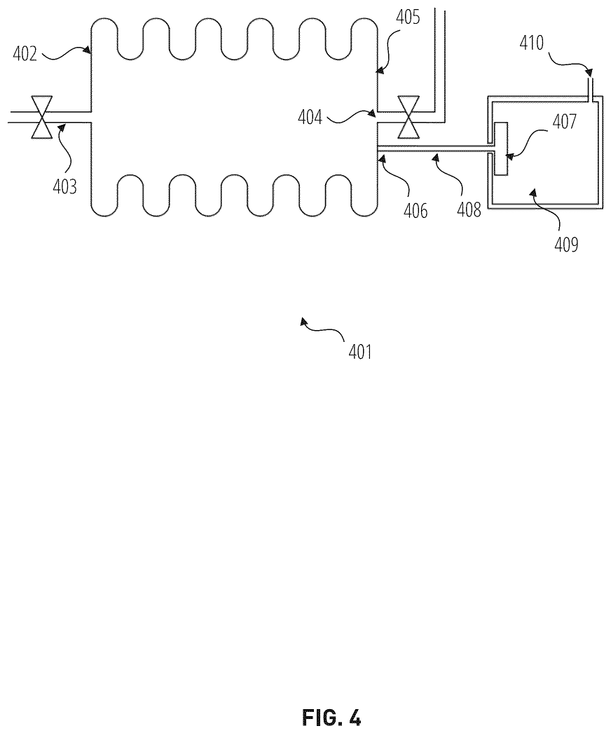

Referring to FIG. 4, a bellows accumulator 401 may comprise an expandable/contractable container 402 having a precursor gas inlet 403 and a precursor gas outlet 404. A first end 405 of the container 402 may be connected to a first end 406 of a push/pull actuator 408. A second end 407 of the push/pull actuator 408 may be floating in a closed volume 409. The push/pull actuator 408 may be moved by changing a gas pressure in the closed volume 409, for example by inserting or removing gas through a gas port of the closed volume 409. By moving the push/pull actuator 408, the bellows container 402 is compressed or expanded and the internal volume thereof is modified.

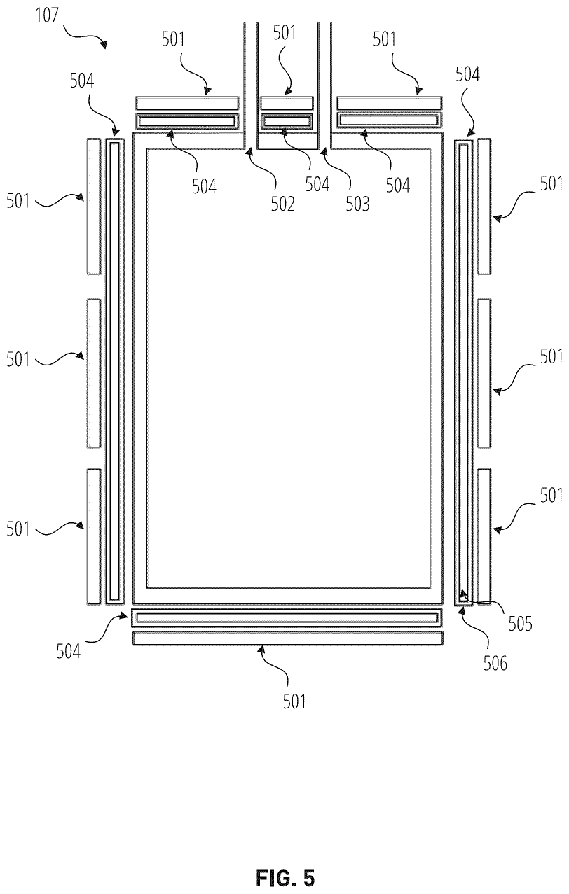

Referring to FIG. 5, in some embodiments, the accumulator vessel 107 comprises an accumulator vessel heater 501 configured to heat the accumulator vessel 107. Maintaining the precursor gas in the accumulator vessel 107 at a set temperature may be important in, for example, calculating an amount of precursor gas provided to the process chamber 102 during a precursor supply process. The accumulator vessel heater 501 may be in the form of a heating jacket arranged to substantially surround the accumulator vessel 107. Gaps or channels in the accumulator vessel heater 501 may be provided to accommodate the accumulator gas inlet 207, the accumulator gas outlet 208, and optionally the actuatable element 205 or parts thereof, for example a rod of a piston. The accumulator vessel heater 501 may comprise one or more heater wire elements for providing resistive heating. The accumulator vessel heater 501 may be controllable by the controller 127.

In some situations, the accumulator vessel heater 501 may not provide a uniform temperature to the accumulator vessel 107. For example, there may be slight variations from the setpoint temperature between heating elements comprised in the accumulator vessel heater 501. This can lead to inaccurate dose calculation. In some embodiments, the accumulator vessel 107 comprises a temperature regulation element 504 disposed between the accumulator vessel heater 501 and the accumulator vessel 107. The temperature regulation element 504 is capable of storing excess energy provided by the accumulator vessel heater 501 and of transmitting a constant temperature to the accumulator vessel 107. This can help to improve temperature uniformity of the accumulator vessel 107.

The temperature regulation element 504 may comprise a phase change material 505. The phase change material 505 may have a phase change temperature which is within a desired temperature range for the accumulator vessel 107, thus providing temperature damping which can reduce under-or overshoot in temperature of the accumulator vessel heater 501. The phase change material 505 may comprise, for example, adipic acid, having a phase change temperature of 152° C., or d-Mannitol, with phase change temp of 165° C. The temperature regulation element 504 may comprise a thermally conductive container 506 for containing the phase change material 505. The thermally conductive container 506 may comprise, for example, aluminum. The thermally conductive container 506 may be configured to allow for volume change of the phase change material 505 upon phase transition.

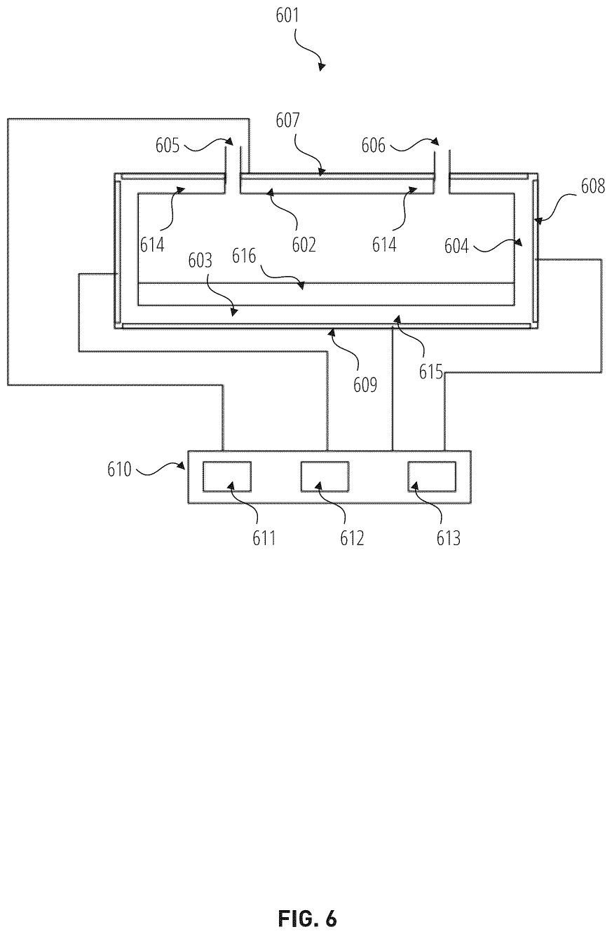

Referring to FIG. 6, an example of a solid state precursor storage vessel 601 which may be comprised in the semiconductor processing apparatus 101 according to embodiments of the present invention is shown. The solid state precursor storage vessel 601 has a top wall 602, a bottom wall 603, and a side wall 604; a gas inlet port 605, and a gas outlet port 606. The gas inlet port 605 may be provided in the top wall 602. The gas outlet port 606 may be provided in the top wall 602. The gas inlet port 605 provides a conduit for precursor gas to flow into the solid state precursor storage vessel 601 and may be in fluid communication with a bulk precursor supply. The gas outlet port 606 provides a conduit for precursor gas to flow out of the solid state precursor storage vessel 601 and may be in fluid communication with an accumulator vessel 107.

The solid state precursor storage vessel 601 comprises a top wall heater 607 for heating the top wall 602, a side wall heater 608 for heating the side wall 604, and a bottom wall heater 609 for heating the bottom wall 603. The top wall heater 607, the side wall heater 608, and the bottom wall heater 609 are individually controllable. The solid state precursor storage vessel 601 may comprise a solid state precursor storage vessel controller 610 comprising a top wall heater controller 611, a side wall heater controller 612, and a bottom wall heater controller 613, each of which are independently operable.

The top wall heater controller 611 may be configured to, during supply of precursor to the solid state precursor storage vessel 601 from the bulk precursor supply, maintain the top wall 602 of the solid state precursor storage vessel 601 at a temperature above a deposition temperature of the precursor gas, so as to avoid deposition of precursor on the top wall 602. The side wall heater controller 612 may be configured to, during supply of precursor to the solid state precursor storage vessel 601 from the bulk precursor supply, maintain the side wall 604 of the solid state precursor storage vessel 601 at a temperature above a deposition temperature of the precursor gas, so as to avoid deposition of precursor on the side wall 604. The bottom wall heater controller 613 may be configured to, during supply of precursor to the solid state precursor storage vessel 601 from the bulk precursor supply, maintain the bottom wall 603 of the solid state precursor storage vessel 601 at a temperature at or below a deposition temperature of the precursor gas so as to cause deposition of the precursor on the bottom wall 603.

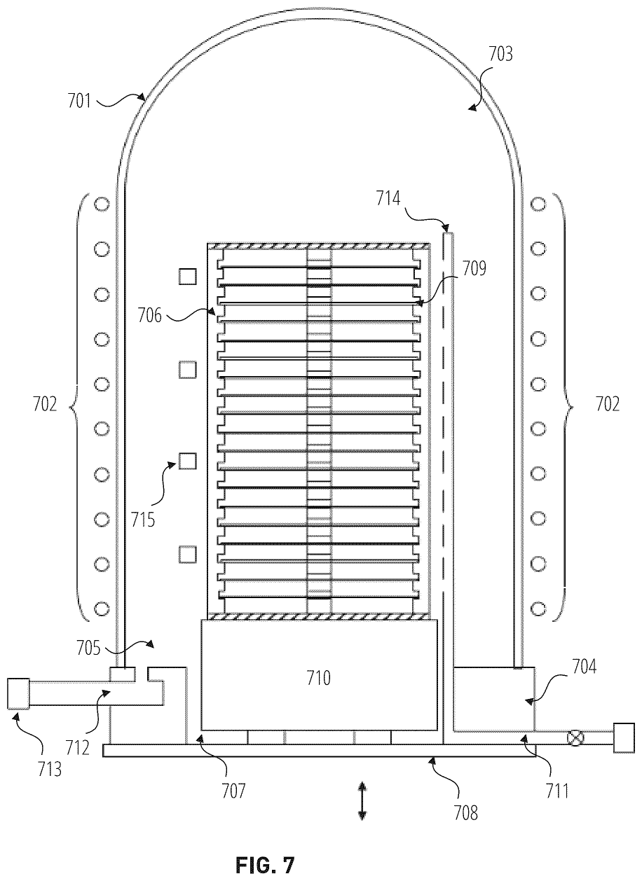

The top wall heater 607 may be considered to be a heater for heating a first section 614 of the solid state precursor storage vessel 601 close to the gas inlet port 605 and/or the gas outlet port 606 and the bottom wall heater 609 may be considered to be a heater for heating a second section 615 of the solid state precursor storage vessel 601 further from the gas inlet port 605. By providing separately controllable heaters for the first section 614 and for the second section 615, the temperatures of these sections can be controlled so as to promote deposition of precursor at or near the second section 615 and to discourage deposition of precursor at or near the first section 614. For example, during refill of the solid state precursor storage vessel 601 with gas precursor, the bottom wall heater 609 may be controlled (e.g. Using the bottom wall heater controller 613) to maintain the bottom wall 603 at a temperature below the deposition temperature of the precursor, and the top wall heater 607 may be controlled (e.g. Using the top wall heater controller 611) to maintain the top wall 602 at a temperature above the deposition temperature of the precursor. The solid state precursor storage vessel 601 is illustrated in FIG. 7 as containing solid state precursor 616, but may at certain points in time be empty of solid state precursor 616, for example before the first filling or between refilling processes.

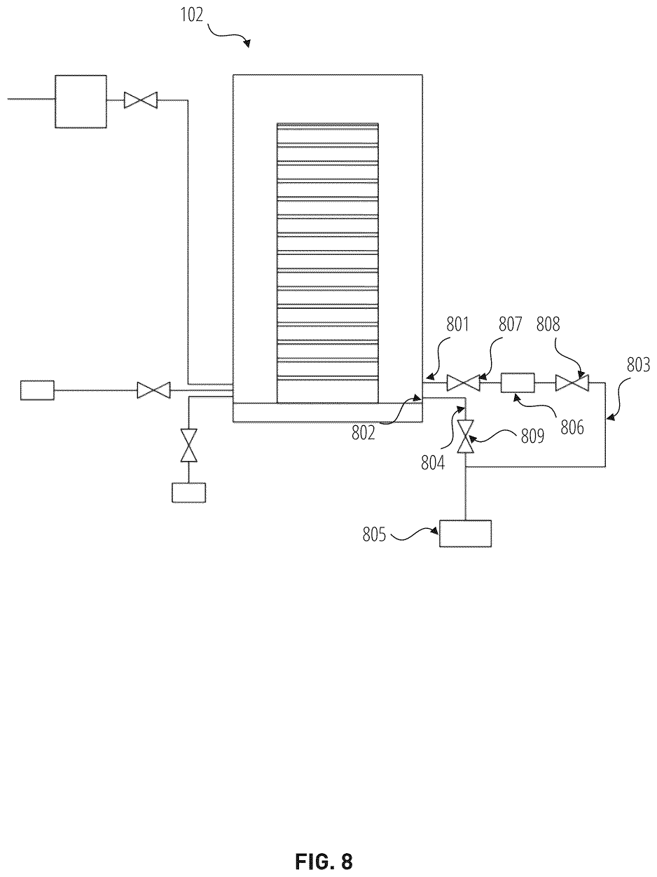

Referring to FIG. 7, an example of a process chamber 701 which may be comprised in the semiconductor processing apparatus 101 is shown in more detail. The present invention is not limited to semiconductor processing apparatus 101 comprising the specific process chamber 701 shown in FIG. 8 and other types of process chamber 701 with similar or different features may be used instead of the process chamber 701 shown in FIG. 8. The process chamber 701 may be generally bell jar shaped. The process chamber may be surrounded by heating means, such as one or more thermally resistive heating coils 702 powered by an electrical power supply (not shown). The heating means provides heat to the process chamber 701 which subsequently causes the interior volume 703 of the process chamber 701 to be heated. The process chamber 701 may be made of quartz, silicon carbide, silicon or another suitable heat resistant material.

The process chamber 701 may be supported at its lower end on a flange 704 for partially closing an open end 705 of the process chamber 701. A substrate boat 706 may enter and/or exit the process chamber via a central furnace opening 707 provided in the flange 704. A vertically movably arranged door 708 may be configured to close off the central furnace opening 707 and may be configured to support the substrate boat 706. The substrate boat 706 is configured to support a plurality of substrates 709. The substrate boat 706 may sometimes be inserted into the process chamber 701 while empty i.e. not supporting any substrates 709. The substrates 709 may in some cases be dummy wafers which are not intended to be used for further manufacture. The substrate boat 706 may support, for example, 100 substrates, 121 substrates, 150 substrates, 170 substrates, or greater than 170 substrates.

The door 708 may be provided with a pedestal 710. The pedestal 710 may be rotated to have the substrate boat 706 rotating. The process chamber 701 comprises at least one process chamber gas flow inlet 711 for providing a flow of gas into the process chamber. The process chamber gas flow inlet 711 may be at least partially comprised in the flange 704. The flange 704 may comprises a process chamber gas exhaust outlet 712 to remove gas from the process chamber. The process chamber gas exhaust outlet 712 may be connected to a vacuum pump 713.

The process chamber gas flow inlet 711 may be configured to provide a flow of one or more of a process gas (e.g. precursor gas), a purge gas, and a cleaning gas into the process chamber. In some embodiments, separate process chamber gas flow inlets 711 may be provided for each of one or more process gases and a purge gas and optionally a cleaning gas.

The process chamber gas flow inlet 711 may be provided with an injector 714 constructed and arranged within the process chamber 701 to extend vertically into the inner space of the process chamber 701 along the wall of the process chamber 701 towards the higher end. The injector 714 may comprise injector openings to inject gas towards the substrates 709. In some embodiments, the injector 714 may comprise multiple injector openings distributed along a vertical direction of the injector. In some embodiments, the injector 714 may comprise a single opening at a top end of the injector 714, being opposite to the end of the injector 714 which connects with the process chamber gas flow inlet 711. In some embodiments, the injector 714 is not provided and the gas flows upwards from the process chamber gas flow inlet 711 without its flow being directed by an injector. In some embodiments, a process chamber gas flow inlet 711 provided with an injector may be provided in addition to an additional process chamber gas flow inlet 711 which is not connected to an injector.

One or more thermocouples 715 may be provided within the process chamber 701 for measuring the temperature inside the process chamber 701. The thermocouples 715 may be provided each within a different heating zone of the process chamber 701 corresponding to a respective heating coil 702.

Referring again to FIG. 1, the semiconductor processing apparatus 101 may comprise a controller 127 configured to control one or more elements of the semiconductor processing apparatus 101. For example, the controller 127 may be configured to control a state of the gas flow control valves, such as the first gas flow control valve 114, the second gas flow control valve 115, the third gas flow control valve 118, the fourth gas flow control valve 119, the fifth gas flow control valve 120, the sixth gas flow control valve 121, the purge gas flow control valve 125, the second process gas flow control valve 123, and/or their respective heaters. The controller 127 may be configured to control the accumulator inlet valve, the accumulator outlet valve, the actuatable element, the accumulator vessel heater. The controller 127 may be configured to control the top wall heater 607, the side wall heater 608, the bottom wall heater 609 of the solid state precursor storage vessels 601, 108. The top wall heater controller 611 may be comprised in the controller 127. The side wall heater controller 612 may be comprised in the controller 127. The bottom wall heater controller 613 may be comprised in the controller 127. The controller 127 may be configured to control the heating coils 702 of the process chamber 102. The controller 127 may be configured to receive data from various sensors comprised in the semiconductor processing apparatus 101, for example the thermocouples 715 of the process chamber 102, 701, and to control one or more elements of the semiconductor processing apparatus 101 based on received data. The controller 127 may store, in a memory, a series of instructions for carrying out a method(s) according to embodiments of the present invention, and may load such instructions into a processor configured to execute the instructions so as to carry out the method(s).

Referring to FIG. 8, in some embodiments, the process chamber 102 comprises more than one gas exhaust outlet. The process chamber 102 may comprise a precursor gas exhaust outlet 801 and a separate reactant/purge gas exhaust outlet 802. The precursor gas exhaust outlet 801 may be in fluid communication with a precursor gas exhaust line 803 and the reactant/purge gas exhaust outlet 802 may be in fluid communication with a reactant/purge gas exhaust line 804 which is separate to the precursor gas exhaust line 803. The precursor gas exhaust line 803 and the reactant/purge gas exhaust line 804 may be recombined upstream of a vacuum pump 805. The reactant may also be referred to as the second process gas.

The precursor gas exhaust line 803 may comprise a precursor trap 806 for condensing precursor gas. The precursor trap 806 may be water-cooled so as to maintain the precursor trap 806 at a temperature below a deposition or condensation temperature of the precursor gas. Since not all of the precursor gas provided to the process chamber 102 is consumed in a deposition process, by collecting unused precursor gas in the precursor trap 806, waste of expensive precursor gas can be reduced. The collected precursor in the precursor trap 806 can be reused in a subsequent deposition process. By keeping the reactant and the precursor separate in separate gas lines when exhausting the process chamber 102, the precursor gas can be prevented from reacting with the reactant and can be recuperated for further use. The precursor gas exhaust line 803 may comprise a first valve 807 upstream of the precursor trap 806 so as to prevent the reactant from entering the precursor trap 806. The precursor gas exhaust line 803 may comprise a second valve 808 downstream of the precursor trap 806 so as to prevent backflow of reactant into the precursor trap 806. The reactant/purge gas exhaust line 804 may comprise a third valve 809. The first, second and third valves allow for selection of exhaust path depending on the process step. During a process step in which precursor gas is provided to the process chamber 102, e.g. Step S202 as is described in more detail hereinafter, the first valve 807 and the second valve 808 in the precursor gas exhaust line 803 may be set to an open state and the third valve 809 in the reactant/purge gas exhaust line 804 may be set to a closed state. During a process step in which reactant gas is provided to the process chamber 102, e.g. Step S204 as is described in more detail hereinafter, the first valve 807 and the second valve 808 in the precursor gas exhaust line 803 may be set to a closed state and the third valve 809 in the reactant/purge gas exhaust line 804 may be set to an open state.

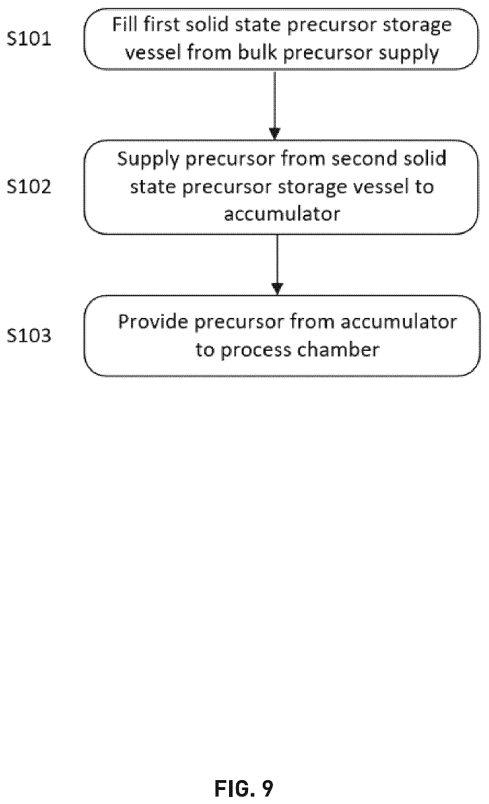

Referring to FIG. 9, a flow chart of a method according to embodiments of the present invention of providing the precursor gas to the process chamber 102 of the semiconductor processing apparatus 101 is shown. The method comprises the steps of causing a first solid state precursor storage vessel 109 of the at least two solid state precursor storage vessels 108 to receive a precursor in gas form and to convert said precursor to a solid state (step S101), causing a second solid state precursor storage vessel 110 of the at least two solid state precursor storage vessels 108 to convert solid state precursor stored therein to gas form and to provide precursor in gas form to the accumulator vessel 107 (step S102), and causing a precursor gas to be provided to the process chamber 102 from the accumulator vessel 107 by actuating the actuatable element (step S103). Step S101 and step S102 are preferably performed simultaneously.

In step S101, causing the first solid state precursor storage vessel 109 to receive a precursor in gas form may comprise causing a precursor gas to be provided to the first solid state precursor storage vessel 109 from the bulk precursor supply 111. Step S101 may comprise setting the third gas flow control valve 118 to an open state. In step S101, the second solid state precursor storage vessel 110 may not be receiving precursor gas from the bulk precursor supply 111, and so step S101 may comprise setting the fourth gas flow control valve 119 to a closed state.

In step S101, causing the first solid state precursor storage vessel 109 to convert the received precursor in gas form to solid state may comprise causing a temperature of a wall of the first solid state precursor storage vessel 109 to be maintained at a temperature which is less than a deposition temperature of the precursor. This causes precursor to condense on a wall of the first solid state precursor storage vessel 109. This deposited precursor can then be stored in the solid state until it is required to be provided to the accumulator vessel 107 in gas state. By storing the precursor in the first solid state precursor storage vessel 109 in the solid state, the time for which the precursor can be stored without significant decomposition is extended considerably in comparison to storing the precursor in gas state. By providing the precursor to the first solid state precursor storage vessel 109 in gas form, issues of clogging or contamination associated with provision of precursor in powder or liquid format can be avoided. Step S101 may comprise causing a temperature of a region of a wall of the first solid state precursor storage vessel 109, such region being close to a gas inlet and/or a gas outlet of the first solid state precursor storage vessel 109, to be maintained at a temperature above a deposition temperature of the precursor. This can help to avoid deposition of precursor in and/or around the inlet and/or outlet, reducing the chance of flow restriction at the inlet and/or outlet. The first solid state precursor storage vessel 109 may therefore comprise one or more individually controllable heaters configured to heat respective areas of the walls of the first solid state precursor storage vessel 109.

In step S102, causing the second solid state precursor storage vessel 110 to convert solid state precursor stored therein to gas form may comprise causing a temperature of the walls of the second solid state precursor storage vessel 110 to be heated to a temperature above a sublimation temperature of the precursor in solid state.

Step S101 and step S102 may be performed substantially simultaneously, that is, while the first solid state precursor storage vessel 109 is undergoing a refill process by receiving and converting gas state precursor to solid state, the second solid state precursor storage vessel 110 is sublimating and providing gas precursor to the accumulator vessel 107. The solid state precursor storage vessels 108 may subsequently switch roles, that is, the first solid state precursor storage vessel 109 sublimates and provides gas precursor to the accumulator vessel 107 while the second solid state precursor storage vessel 110 receives and converts gas precursor to solid state. This allows the supply of precursor to the accumulator vessel 107 to be continuously available, which increases the throughput of the semiconductor processing apparatus 101.

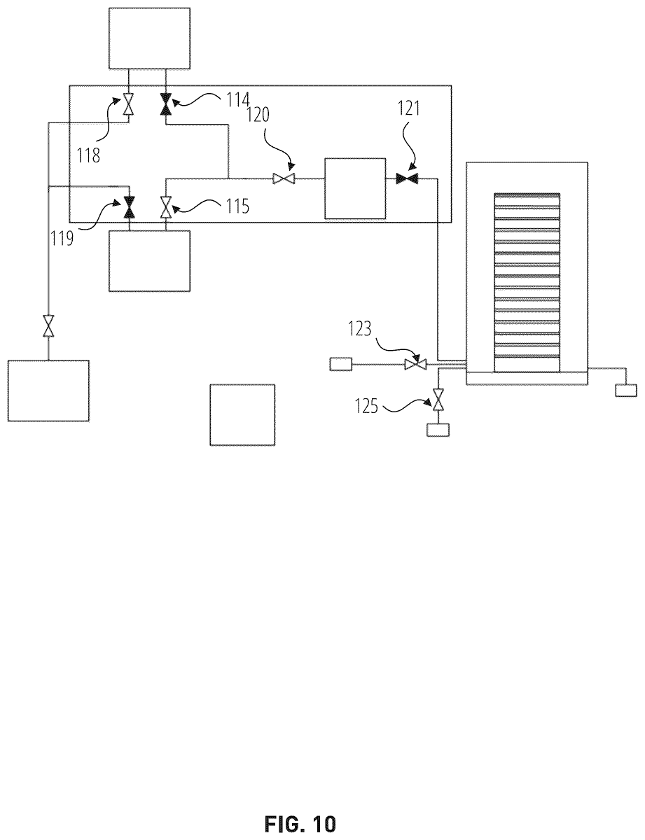

The gas flow control valve states during steps S101 and S102 are shown in FIG. 10. During supply of precursor to the first solid state precursor storage vessel 109 from the bulk precursor supply 111, the first solid state precursor storage vessel 109 does not provide precursor gas to the accumulator vessel 107, and so the first gas flow control valve 114 is set to an closed state and the third gas flow control valve 118 is set to an open state. During supply of precursor from the second solid state precursor storage vessel 110 to the accumulator vessel 107, the second solid state precursor storage vessel 110 does not receive precursor from the bulk precursor supply, and so the second gas flow control valve 115 is set to an open state and the fourth gas flow control valve 119 is set to a closed state. The fifth gas flow control valve 120, if present, is set to an open state and the sixth gas flow control valve 121, if present, may be set to a closed state. The purge gas flow control valve 125 and the second process gas flow control valve 123 may be open or closed depending on the status of the process chamber 102, for example depending on which stage of a layer deposition process is being carried out. For example, steps S101 and S102 may take place during a purge gas provision step and/or a second process gas provision step in a layer deposition process.

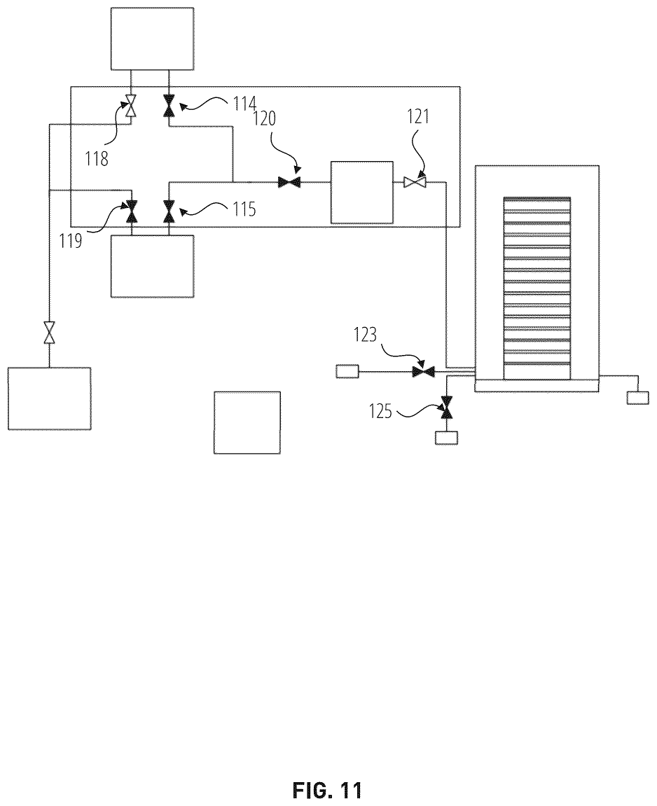

The gas flow control valve states during step S103 are shown in FIG. 11. Once a sufficient quantity of gas precursor has been accumulated in the accumulator vessel 107, the sixth gas flow control valve 121 is set to an open state and the fifth gas flow control valve 120 may be set to an open or a closed state. The actuatable element is actuated. This allows precursor gas to flow from the accumulator vessel 107 to the process chamber 102. During step S103, the second process gas flow control valve 123 and the purge gas flow control valve 125 are closed.

Step S103 may comprise, once a sufficient quantity of gas precursor has been accumulated in the accumulator vessel 107, setting the fifth gas flow control valve 120 and the sixth gas flow control valve 121 to a closed state and heating the precursor gas in the accumulator vessel. The precursor gas may be heated, for example, using the accumulator vessel heater, or by applying energy using a laser or microwave radiation device. By heating the precursor gas in the accumulator vessel, the pressure of the precursor gas is increased and thus the peak flow rate to the process chamber 102 is increased once the sixth gas flow control valve 121 is opened. The fifth gas flow control valve 120 and the sixth gas flow control valve 121 may be heated during the precursor gas heating step so as to avoid condensation of precursor at the valves.

After step S103 is completed, the process may be repeated, i.e. Steps S101, S102, and S103 are again performed. Steps S101, S102, and S103 may form part of a deposition process for depositing a layer of a desired thickness on a plurality of substrates 103 in the process chamber 102. The deposition process may include a number of repetitions of steps S101, S102, and S103 followed by removal of the plurality of substrates 103 from the process chamber 102, loading of a different plurality of substrates 103 into the process chamber 102, and a further deposition process for depositing a layer of a desired thickness on the different plurality of substrates 103 comprising repetition of steps S101, S102, and S103.

The functions of the first solid state precursor storage vessel 109 and the second solid state precursor storage vessel 110 may be swapped, that is, in step S101 the second solid state precursor storage vessel 110 is caused to receive a precursor in gas form and to convert said precursor to a solid state, and in step S102 the first solid state precursor storage vessel 109 is caused to convert solid state precursor stored therein to gas form and to provide precursor in gas form to the accumulator vessel 107. This swapping of functions may take place once the quantity of precursor in the second solid state precursor storage vessel 110, being the solid state precursor storage vessel which is supplying precursor to the accumulator vessel 107, has decreased to a quantity which is not sufficient for providing a required amount of precursor gas for a required number of repetitions of step S103. For example, in some embodiments, the at least two solid state precursor storage vessels may each be positioned on a load scale to measure the amount of precursor stored therein and once the measured quantity is below a threshold value, the controller may cause the functions of the first solid state precursor storage vessel 108 and the second solid state precursor storage vessel 109 to be swapped. In some embodiments, the functions of the first solid state precursor storage vessel 108 and the second solid state precursor storage vessel 109 may be swapped automatically between deposition processes.

The first solid state precursor storage vessel 109 and the second solid state precursor storage vessel 110 may continue to exchange functions dependent on the amount of precursor remaining or between deposition processes. Depending on the amount of precursor required for depositing a layer, the functions may not be swapped between every deposition process.

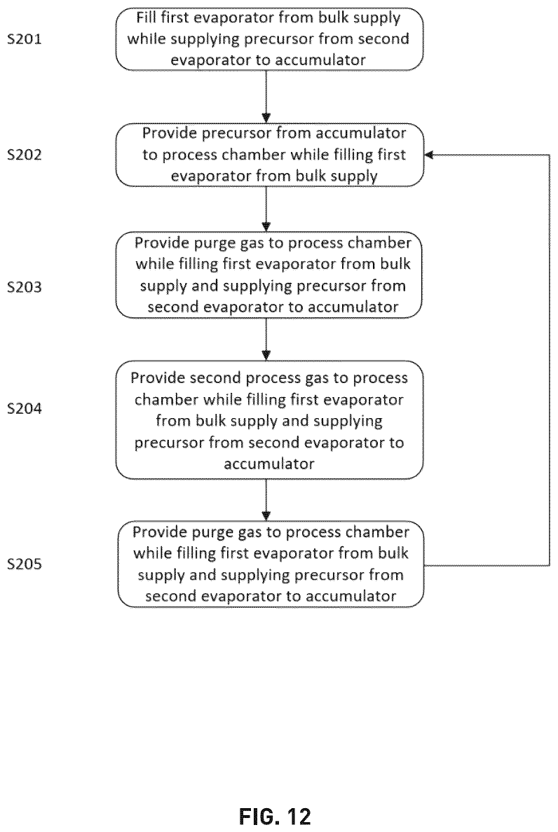

Referring to FIG. 12, a flow chart of a deposition method according to embodiments of the present invention is shown. The deposition method is carried out using a semiconductor processing apparatus 101 according to embodiments of the present invention. The deposition method comprises the following steps:

In step S201, the first solid state precursor storage vessel 109 is caused to receive gas precursor from the bulk precursor supply 111 while precursor gas is supplied from the second solid state precursor storage vessel 110 to the accumulator vessel 107. In step S201, the third gas flow control valve 118 is set to an open state and the fourth gas flow control valve 119 is set to a closed state; the first gas flow control valve 114 is set to a closed state and the second gas flow control valve 115 is set to an open state; the fifth gas flow control valve 120 may be set to an open state or a closed state and the sixth gas flow control valve 121 is set to a closed state. This step may be seen as a preparation or pre-filling step and may be performed once at the beginning of a series of repetitions of steps S202 to S205.

In step S202, precursor gas is provided from the accumulator vessel 107 to the process chamber 102 by actuating the actuatable element while the first solid state precursor storage vessel 109 is caused to receive gas precursor from the bulk precursor supply 111. In step S202, the third gas flow control valve 118 is set to an open state and the fourth gas flow control valve 119 is set to a closed state; the first gas flow control valve 114 is set to a closed state and the second gas flow control valve 115 may be set to an open state or a closed state; the fifth gas flow control valve 120 may be set to the same state as that of the second gas flow control valve; and the sixth gas flow control valve 121 is set to an open state. The second process gas flow control valve 123 and the purge gas flow control valve 125 are set to a closed state. By providing precursor gas to the process chamber 102, the precursor gas may react with the surface of the plurality of substrates in a self-limiting manner so as to form a layer comprising the precursor on a surface of the plurality of substrates in the process chamber 102.

In step S203, a purge gas is provided to the process chamber 102 while causing the first solid state precursor storage vessel 109 to receive gas precursor from the bulk precursor supply 111 and causing the second solid state precursor storage vessel 110 to provide gas precursor to the accumulator vessel 107. In step S203, the third gas flow control valve 118 is set to an open state and the fourth gas flow control valve 119 is set to a closed state; the first gas flow control valve 114 is set to a closed state and the second gas flow control valve 115 is set to an open state; the fifth gas flow control valve 120 is set to an open state and the sixth gas flow control valve 121 is set to a closed state. The purge gas flow control valve 125 is set to an open state and the second process gas flow control valve 123 is set to a closed state. By providing the purge gas to the process chamber 102, any precursor gas remaining in the process chamber 102 from step S202 may be removed from the process chamber 102 via the process chamber gas exhaust outlet 106.

In step S204, a second process gas is provided to the process chamber 102 while causing the first solid state precursor storage vessel 109 to receive gas precursor from the bulk precursor supply 111 and causing the second solid state precursor storage vessel 110 to provide gas precursor to the accumulator vessel 107. In step S204, the third gas flow control valve 118 is set to an open state and the fourth gas flow control valve 119 is set to a closed state; the first gas flow control valve 114 is set to a closed state and the second gas flow control valve 115 is set to an open state; the fifth gas flow control valve 120 is set to an open state and the sixth gas flow control valve 121 is set to a closed state. The purge gas flow control valve 125 is set to a closed state and the second process gas flow control valve 123 is set to an open state. By providing the second process gas to the process chamber 102, the second process gas may react with a surface of the plurality of substrates so as to form a layer comprising a component of the second process gas and the precursor on the plurality of substrates.

In step S205, a purge gas is provided to the process chamber 102 while causing the first solid state precursor storage vessel 109 to receive gas precursor from the bulk precursor supply 111 and causing the second solid state precursor storage vessel 110 to provide gas precursor to the accumulator vessel 107. In step S205, the third gas flow control valve 118 is set to an open state and the fourth gas flow control valve 119 is set to a closed state; the first gas flow control valve 114 is set to a closed state and the second gas flow control valve 115 is set to an open state; the fifth gas flow control valve 120 is set to an open state and the sixth gas flow control valve 121 is set to a closed state. The purge gas flow control valve 125 is set to an open state and the second process gas flow control valve 123 is set to a closed state. By providing the purge gas to the process chamber 102, any second process gas remaining in the process chamber 102 from step S204 may be removed from the process chamber 102 via the process chamber gas exhaust outlet 106.

The method may comprise repeating steps S202 to S205 until a layer of a desired thickness is formed on the plurality of substrates 103 in the process chamber 102. The method may comprise, once the layer of desired thickness has been formed on the plurality of substrates 103 in the process chamber 102, performing a substrate swap procedure comprising cooling the process chamber 102 to an unloading temperature, removing the plurality of substrates 103 from the process chamber 102, unloading the plurality of substrates 103 from the substrate boat, loading a different plurality of substrates 103 into the substrate boat, loading the substrate boat into the process chamber 102, pumping down the process chamber 102, stabilising the temperature of the process chamber 102 and repeating steps S201 to S205 to deposit a layer of required thickness onto the different plurality of substrates 103. Step S201 may take place during the substrate swap procedure.

The method may comprise monitoring the quantity of precursor in the solid state precursor storage vessel which is supplying the accumulator vessel 107, for example using load scales, and swapping the functions of the first solid state precursor storage vessel 109 and the second solid state precursor storage vessel 110 once the quantity is below a threshold value. The controller 127 may be configured to carry out such monitoring and control, for example by receiving measurements from the load scales, comparing the received measurements with a threshold value, and, if the received measurement is below the threshold value, causing the functions of the first solid state precursor storage vessel 109 and the second solid state precursor storage vessel 110 to be swapped, for example by controlling gas flow control valves and heaters of the solid state precursor storage vessels.

The precursor may comprise, for example, molybdenum oxychloride, hafnium chloride, molybdenum chloride. The second process gas may comprise, for example, hydrogen, ammonia, ozone, water vapour. The purge gas may comprise, for example, nitrogen, argon. In some embodiments, the precursor comprises molybdenum oxychloride, the second process gas comprises ammonia, and the purge gas comprises hydrogen. In some embodiments, the precursor comprises molybdenum oxychloride, the second process gas comprises hydrogen, and the purge gas comprises argon.

The method may comprise, before step S201, providing a plurality of substrates in a substrate boat in the semiconductor processing apparatus 101.

For purposes of summarizing the invention and the advantages achieved over the prior art, certain objects and advantages of the invention have been described herein above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught or suggested herein without necessarily achieving other objects or advantages as may be taught or suggested herein.

All of these embodiments are intended to be within the scope of the invention herein disclosed. These and other embodiments will become readily apparent to those skilled in the art from the following detailed description of certain embodiments having reference to the attached figures, the invention not being limited to any particular embodiment(s) disclosed.

What is claimed is:

1. A semiconductor processing apparatus comprising:
a process chamber configured to receive a plurality of substrates;
at least one accumulator vessel in fluid communication with the process chamber, configured to store a precursor in gas form; and
at least two solid state precursor storage vessels, each being configured to receive a precursor in gas form, to cause said received gas form precursor to be converted to a solid state inside the respective solid state precursor storage vessel, and to cause said solid state precursor to be converted to gas phase;
wherein each of the at least two solid state precursor storage vessels are in fluid communication with the at least one accumulator vessel so as to allow provision of precursor in gas form to the accumulator vessel;
wherein the at least one accumulator vessel comprises an actuatable element configured to cause an internal volume of the at least one accumulator vessel to be changed upon actuation.

2. The semiconductor processing apparatus of claim 1, wherein the at least one accumulator vessel comprises a gas inlet for conducting gas into the respective accumulator vessel and a gas outlet for conducting gas out of the accumulator vessel, wherein the actuatable element is configured to push a gas out of the accumulator vessel via the gas outlet and to draw gas into the respective accumulator vessel via the gas inlet.

3. The semiconductor processing apparatus of claim 2, wherein the gas inlet comprises a gas inlet valve and the gas outlet comprises a gas outlet valve, the semiconductor processing apparatus further comprising a controller configured to, in a gas draw mode, control the gas inlet valve to have an open state and the gas outlet valve to have a closed state, and to subsequently cause the actuatable element to be actuated so as to cause a decrease in vapor pressure in one of the at least two solid state precursor storage vessels.

4. The semiconductor processing apparatus of claim 3, wherein the controller is configured to, in a gas supply mode, control the gas inlet valve to have a closed state and the gas outlet valve to have an open state, and to subsequently cause the actuatable element to be actuated so as to push a gas out of the accumulator vessel.

5. The semiconductor processing apparatus of claim 1, wherein the actuatable element is a piston or a bellows.

6. The semiconductor processing apparatus of claim 1, wherein the at least one accumulator vessel comprises an accumulator vessel heater.

7. The semiconductor processing apparatus of claim 6, wherein the accumulator vessel heater comprises a heating jacket arranged to substantially surround the accumulator vessel.

8. The semiconductor processing apparatus of claim 7, comprising a temperature regulation element comprising a phase change material between the heating jacket and the accumulator vessel.

9. The semiconductor processing apparatus of claim 1, comprising at least two accumulator vessels connected in parallel.

10. The semiconductor processing apparatus of claim 1, comprising a precursor exhaust path for removing a precursor gas from the process chamber and a reactant exhaust path for removing a reactant gas different to the precursor gas from the process chamber, wherein the precursor exhaust path is separated from the reactant exhaust path.

11. The semiconductor processing apparatus of claim 10, wherein the precursor exhaust path comprises a trap for collecting precursor.

12. The semiconductor processing apparatus of claim 1, further comprising:
a first gas line for providing a fluidic connection between a first solid state precursor storage vessel of the at least two solid state precursor storage vessels and the accumulator vessel; and a second gas line for providing a fluidic connection between a second of the at least two solid state precursor storage vessels and the accumulator vessel, wherein the first gas line comprises a first gas flow control valve and the second gas line comprises a second gas flow control valve.

13. The semiconductor processing apparatus of claim 1, further comprising:
a third gas line for providing a fluidic connection between a bulk precursor supply for providing a precursor in gas form and a first of the at least two solid state precursor storage vessels, the third gas line comprising a third gas flow control valve; and
a fourth gas line for providing a fluidic connection between the bulk precursor supply and a second of the at least two solid state precursor storage vessels, the fourth gas line comprising a fourth gas flow control valve.

14. The semiconductor processing apparatus of claim 1, comprising a fifth gas flow control valve disposed upstream of the accumulator vessel and configured to control a gas flow into the accumulator vessel from any of the at least two solid state precursor storage vessels; and a sixth gas flow control valve disposed downstream of the accumulator vessel and configured to control a gas flow from the accumulator vessel into the process chamber.

15. A method of providing a precursor gas to a process chamber of a semiconductor processing apparatus, the semiconductor processing apparatus comprising a process chamber configured to receive a plurality of substrates;
at least one accumulator vessel in fluid communication with the process chamber, configured to store a precursor in gas form, the at least one accumulator vessel comprising an actuatable element configured to cause an internal volume of the at least one accumulator vessel to be changed upon actuation; and
at least two solid state precursor storage vessels, each being configured to receive a precursor in gas form, to cause said received gas form precursor to be converted to a solid state inside the respective solid state precursor storage vessel, and to cause said solid state precursor to be converted to gas phase;
wherein each of the at least two solid state precursor storage vessels are in fluid communication with the at least one accumulator vessel so as to allow provision of gas phase precursor to the at least one accumulator vessel;
wherein the method comprises:
i) causing a first solid state precursor storage vessel of the at least two solid state precursor storage vessels to receive a precursor in gas form and to convert said precursor to a solid state;
ii) causing a second solid state precursor storage vessel of the at least two solid state precursor storage vessels to convert solid state precursor to gas form and to provide precursor in gas form to the at least one accumulator vessel; and
iii) causing a precursor gas to be provided to the process chamber from the at least one accumulator vessel by actuating the respective actuatable element.

16. The method of claim 15, wherein steps i) and ii) are performed substantially simultaneously.

17. The method of claim 15 wherein step ii) and step iii) do not overlap substantially in time.

18. The method of claim 15, wherein step iii) comprises, before actuating the actuatable element, heating the precursor gas.

19. A method of forming a layer on a plurality of substrates using the semiconductor processing apparatus of claim 1, the method comprising the steps of:
causing the first solid state precursor storage vessel to receive gas precursor from the bulk precursor supply while supplying precursor from the second solid state precursor storage vessel to the accumulator vessel;
providing precursor from the accumulator vessel to the process chamber by actuating the actuatable element while causing the first solid state precursor storage vessel to receive gas precursor from the bulk precursor supply;
providing a purge gas to the process chamber while causing the first solid state precursor storage vessel to receive gas precursor from the bulk precursor supply and causing the second solid state precursor storage vessel to provide gas precursor to the accumulator vessel;
providing a second process gas to the process chamber while causing the first solid state precursor storage vessel to receive gas precursor from the bulk precursor supply and causing the second solid state precursor storage vessel to provide gas precursor to the accumulator vessel; and
providing a purge gas to the process chamber while causing the first solid state precursor storage vessel to receive gas precursor from the bulk precursor supply and causing the second solid state precursor storage vessel to provide gas precursor to the accumulator vessel.

20. The semiconductor processing apparatus of claim 1, wherein the precursor comprises molybdenum.
